(19) United States
(12) Patent Application Publication
(10) Pub. No.: US 2009/0250816 A1
(43) Pub. Date: Oct. 8, 2009

(54) ULTRA-THIN DIFFUSION-BARRIER LAYER FOR CU METALLIZATION

(75) Inventors: Tsung Shune CHIN, Baoshan Township (TW); Ting Yi Lin, Huatan Township (TW); Huai Yu Cheng, Hsinchu City (TW); Jau Shiung Fang, Huwei Township (TW); Chin Fu Chiu, Kaohsiung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: Tsung Shune CHIN, Baoshan Township (TW)

(21) Appl. No.: 12/115,300

(22) Filed: May 5, 2008

(30) Foreign Application Priority Data
Apr. 2, 2008 (TW) 097111990

(51) Int. Cl. H01L 23/52

(52) U.S. Cl. 257/751; 257/E23.141

(57) ABSTRACT

Diffusion barrier layer is required during copper metallization in IC processing to prevent Cu from diffusion into the contacting silicon material and reacting to form copper silicide, which consumes Cu and deteriorates electrical conduction. With decreasing feature sizes of IC devices, such as those smaller than 90 nano-meter (nm), the thickness of diffusion barrier layer must be thinner than 10 nm. For example, a thickness of 2 nm will be called for at the feature size 27 nm. Disclosed in the present invention is ultra-thin barrier materials and structures based on tantalum silicon carbide, and its composite with another metallic layer Ru film. The retarding temperature, by which no evidence of copper diffusion can be identified, is 600˜850° C. depending on thickness, composition and film structure, at a thickness 1.6˜5 nm.

### CROSS REFERENCE TO RELATED APPLICATION

This application claims the priority benefit of Taiwan Patent Application Serial Number 097111990, filed Apr. 2, 2008, the full disclosure of which is incorporated herein by reference.

### BACKGROUND OF THE INVENTION

1. Field of the Invention

The present invention generally relates to a diffusion barrier for copper metallization of semiconductor. More specifically, the diffusion barrier composes of elements selected from tantalum, silicon, carbon, and ruthenium. The barrier structure comprises the stacking sandwich of Si/Ta—Si—C/Cu or Si/Ta—Si—C/Ru/Cu with the optimization of composition and layer thickness.

2. Description of the Related Art

As the feature size of electronic devices in integrated circuit (IC) technology is continuously scaling down to less than 0.18 micrometer (μm), traditional aluminum interconnection has failed to meet the requirements. Copper has been used to replace aluminum for deep sub-micron devices due to its lower electrical resistivity and better resistance to electro-migration when copper is compared with those of aluminum. However, the copper tends to form intermetallic compounds between Si and Cu, specifically at high processing temperatures. This leads to consumption of the copper and increase of electrical resistivity and eventually deteriorates the performance of devices. Thus, it is essential to seek for suitable diffusion barrier materials which keep silicon from direct contact with copper. This barrier is a layer and should be thin, low resistivity, substantially non-reacting with both silicon (Si) and copper (Cu), and capable of retarding Cu penetration. This is particularly true at ever-decreasing feature-size in ultra large scale integration (ULSI) processing technology, which calls for a thinner and thinner barrier thickness.

According to the predication of International Technology Roadmap for Semiconductor (ITRS), trench width, barrier thickness and via resistivity are shown in Table I as below. In 2016, the barrier thickness will be reduced eventually to 2 nano-meter (nm) for a trench width of 27 nm of technology node.

TABLE I
Technology nodes for trench width, barrier thickness and via
resistivity as stated by the ITRS.

| | Year of production: | | | | | |
|---|---|---|---|---|---|---|
| | 2004 | 2007 | 2010 | 2013 | 2016 | 2018 |
| Trench width | 107 | 76 | 54 | 38 | 27 | 21 |
| (nm) | | | | | | |
| Barrier thickness | 8 | 5.6 | 4 | 2.8 | 2 | 1.6 |
| (nm) | | | | | | |
| Via resistivity | 0.09 | 0.05 | 0.032 | 0.016 | 0.0076 | 0.005 |
| (μΩ m²) | | | | | | |

However, the diffusion barriers at such a thin thickness yet required to simultaneously maintain properties like low resistivity, highly thermal stability and high failure temperature are extremely difficult. The conventionally used Ta and TaN diffusion barriers failed to satisfy the strict challenges. In fact, most binary Ta-based barriers at the limited thickness face premature failure at a relatively low temperature, such as below 500° C. This is due to their columnar structure and the formation of crystalline Ta-silicides. Exploration of ternary diffusion barriers with high thermal stability at a thin thickness smaller than 10 nm has been rigorously involved. Highly thermal-stable ternary diffusion barriers, such as TaSiN, TaGeN, TiAlN, and WGeN, were thus proposed for the prevention of Cu penetration. Other alternatives to tackle this problem were proposed to use bi-layer such as Ru/TaN with a total thickness of 10 nm being stable up to 750° C. for 1 minute, and tri-layer such as TiN(5 nm)/Al(2 nm)/TiN(10 nm) with a total thickness over 17 nm being stable up to 700° C. for 30 minutes. The thinnest mono-layer barrier known to current inventors is the report of a 5-nm-thick Ru stable up to 300° C. for 10 minutes. However, precise control of nitrogen content in ternary nitride films during film deposition is quite difficult. A substantial change in film composition and electrical properties will be resulted from a tiny variation in partial pressure of nitrogen thus nitrogen content in the film. This increases the complexity of IC processing control. According to the research by T. S. Chin et al. the resistivity of diffusion barrier suddenly arises from 0.15 to 1.21 Ω-cm at a slight difference in nitrogen concentration from 50.7% to 52.8%. Carbon is a solid refractory element and is used in this invention to substitute nitrogen. This leads to a group of ternary Ta-Si carbides with electrical properties and thermal stability controllable by film composition and thickness. And the Ta, Si and C elements have been routinely adopted in nowadays ULSI technologies; the Ta—Si—C layer should be highly compatible with IC processing technology.

In the related patents, Lexmark Inc. has disclosed some Ta-based materials (including Ta—Si—C) as a resistive heater in inject printer. The resistive heaters designed in various sizes and dimensions were capable of obtaining different heating efficiency. D. H. Triyoso et al proposed a Ta—Si—C layer for an inserted-layer in the metal gate of IC devices by atomic layer deposition (ALD). The transient layer Ta₆₀Si₂₂C₁₈ is capable of enhancing thermal stability of metal gate and reducing leakage current when Ta—Si—C is still in amorphous state with excellent thermal stability to withstand 1000° C. post-annealing. Comparing Ta—Si—C materials used in our invention with those used in the two prior arts, the composition is obviously not the same. And their use as the diffusion barrier for Cu metallization was not taught in the prior arts.

### SUMMARY OF THE INVENTION

The goal of the present invention is to develop ultra-thin Ta—Si—C films and the layer structure thereof as a diffusion barrier for the Cu metallization of semiconductor devices, wherein Ta—Si—C was sandwiched between metallic Cu layer and Si material. The Ta—Si—C is used to prevent Cu atom from diffusing to Si materials. The other goal of our invention is to develop the composite diffusion barrier for the Cu metallization of semiconductor devices, wherein the composite diffusion barrier is composed of an ultra-thin Ta—Si—C film and a metallic ruthenium (Ru). The Ru layer is positioned between metallic Cu and Ta—Si—C film into a sandwiched structure. The composite diffusion barrier of Ru/Ta—Si—C is used to retard Cu diffusion into Si material and reduce the total electrical resistivity of diffusion barrier.

In order to realize the previously stated goals, we also performed examples simulating Cu metallization of semiconductor processing technology. These were done by providing sandwiched structures, which included a layer of copper thin film, a layer of Ta—Si—C diffusion barrier, and Si materials. The diffusion barrier Ta—Si—C was positioned between metallic Cu and Si materials. Alternatively, an extra Ru layer was inserted between Cu and the Ta—Si—C layer. The composition of Ta—Si—C diffusion barrier is expressed as Ta(Si_{y}C_{z})ₘ, where y, z, and m represent the atomic ratio for each element of Ta, Si and C. The atomic ratio of y, z, and m needs to obey the following relationships and limitations:

0.7<m<2.5,

0.9<y/z<9, and y+z=1.

However, Ta—Si—C thin film will easily take up the fourth element (i.e. oxygen) from the vacuum or ambient environment during preparation procedures of Cu metallization in semiconductor processing, wherein the oxygen incorporation in the thin film is positive to the diffusion barrier performance to prevent Cu diffusion at higher temperatures. For one other example, the diffusion barrier is comprised of an extra metallic Ru thin film, which was introduced in between Ta—Si—C thin film and Cu thin film. In our invention ultra-thin diffusion barrier materials were disclosed by a single layer of ternary Ta—Si—C and two layers of composite Ru/Ta—Si—C, respectively, which both show high thermal stability to sustain high annealing treatment at 600˜850° C., depending on the thickness, composition, and structure of the barrier. The proposed material systems have benefits in high compatibility with current semiconductor processing and are simple to prepare. Besides, Ta—Si—C and Ru/Ta—Si—C diffusion barriers, with a thickness 1.6 nm and thicker, can sustain well the blocking ability to Cu penetration at higher temperatures and the avoidance of forming copper silicides, which are detrimental to the performance of devices. The foregoing, as well as additional objectives, features and advantages of the invention will be more readily apparent from the following detailed description, which proceeds with reference to the accompanying drawings.

### BRIEF DESCRIPTION OF THE DRAWINGS

FIG. 1a is a schematic cross-sectional view of a sandwiched structure of Ta—Si—C diffusion barrier according to an embodiment of the present invention, wherein the sandwiched structure is prepared by CVD or PVD in IC technology, and the sandwich structure 100, the metallic Cu thin film 110, silicon material 120, the diffusion barrier layer 130 and the Ta—Si—C material 132 are shown.

FIG. 1b is a schematic cross-sectional view of a sandwiched structure of composite Ru/Ta—Si—C diffusion barrier according to another embodiment of the present invention, wherein Ru is also prepared by CVD or PVD, and positioned between Cu and Ta—Si—C, and a metallic Ru film 134 is shown.

FIG. 2 shows X-ray diffraction patterns of the Ta—Si—C diffusion-barrier with different compositions after post-annealing at 800° C. for 30 minutes.

FIG. 3 shows electrical resistivity of Ta—Si—C thin films with different compositions.

FIG. 4 shows the change in room temperature sheet resistance of 5 nm thick sandwich structures: (a) Si/Ta(Si_{0.6}C_{0.4})_{1.5}/Cu (b) Si/Ta(Si_{0.5}C_{0.5})₂/Cu (C) Si/Ta(Si_{0.97}C_{0.03})_{1.9}/Cu after annealing for 1 minute at temperature shown on abscissa.

FIG. 5 shows X-ray diffraction patterns of Si/Ta(Si_{0.5}C_{0.5})₂/Cu thin film after annealing at temperatures shown.

FIG. 6 shows the change in room temperature sheet resistance of 2 nm thick Ta—Si—C films, with composition shown on each curve, after annealing for 1minute at the temperature shown on abscissa.

FIG. 7 shows the change in room temperature sheet resistance of composite diffusion layer with the sandwiched structures: (a) Si/Ta(Si_{0.6}C_{0.4})_{1.5}/Ru/Cu (b) Si/Ta(Si_{0.5}C_{0.5})₂/Ru/Cu after annealing for 1 minute at the temperature shown on abscissa, wherein both thickness of Ru and Ta—Si—C is well-controlled at 1 nm.

### DETAILED DESCRIPTION OF THE PREFERRED EMBODIMENT

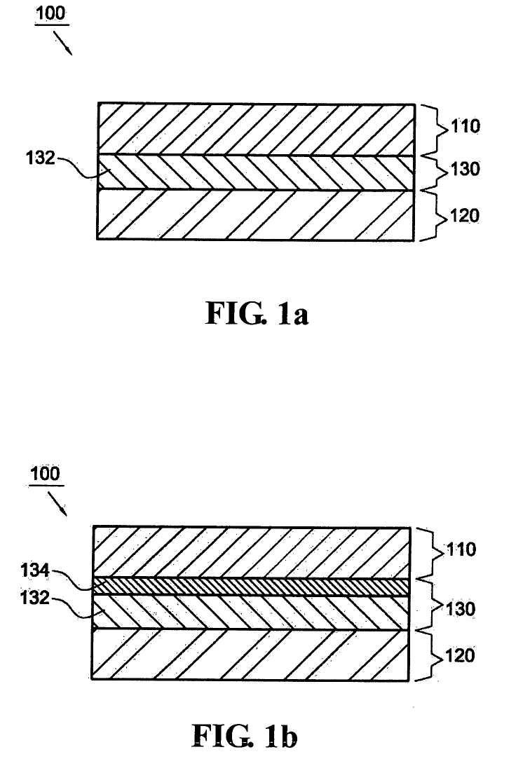

FIG. 1a shows the schematic sandwiched structure 100 for copper (Cu) metallization of semiconductor devices according to an embodiment of the present invention. The sandwiched structure 100 includes a metallic Cu thin film 110, a silicon (Si) material 120, and a diffusion barrier layer 130. The diffusion barrier layer 130 is positioned in between the metallic Cu thin film 110 and the Si material 120 and includes a Ta—Si—C thin film 132, wherein Ta and C represent tantalum and carbon respectively. Such a sandwich structure is used to prevent Cu atoms in metallic Cu thin film (110) from diffusing to the Si material 120, wherein the Si material 120 can be Si wafer or Si-based films used in IC devices.

In order to examine the performances of the Ta—Si—C thin film 132 in thermal stability and the ability of retarding Cu diffusion at high temperatures, the designed material of the Ta—Si—C thin film 132 is a Ta(Si_{y}C_{z})ₘ, which was composed of Ta, Si, and C, wherein y, z and m represent the atomic ratio for each element of Ta, Si and C and obey the following relationships and limitations:

0.7<m<2.5,

0.9<y/z<9, and y+z=1

The Ta—Si—C thin film 132 can be prepared by the methods of chemical vapor deposition (CVD) and physical vapor deposition (PVD) known to one who is skilled in this art. In the embodiments in present invention Ta—Si—C thin film 132 was prepared by dual-targets magnetron co-sputtering technique of PVD method. The Ta—Si—C thin film 132 was deposited onto the cleaned Si material 120 by applying various powers (Watt) to a TaSi₂ target (radio-frequency (RF) power supply) and a carbon target (direct-current (DC) power supply), respectively; at low pressure, 10⁻¹ Torr˜10⁻⁶ Torr. The choice of sputtering power of the respective target determined composition and thickness (such as 5 nm, 2 nm, and 1.6 nm, respectively) of the diffusion barrier layer 130.

In FIG. 1b, for another embodiment, the diffusion barrier layer 130 further includes a metallic Ru thin film 134, wherein Ru represents ruthenium. The metallic Ru thin film 134 is positioned between the Ta—Si—C thin film 132 and the metallic Cu thin film 110. The metallic Ru thin film 134 here was designed to reduce electrical resistivity in order to enhance thermal stability of the diffusion barrier layer 130. For example, the Ru thin film 134 having a thickness of 1 nm was deposited onto the Ta—Si—C thin film 132 having a thickness of 1 nm by the method of DC or RF sputtering.

The thickness of thin films deposited at different sputtering powers was measured by the α-stepper. And then film thickness versus sputtering power was established. The designated thickness of diffusion barrier layer and its composition can be tuned by different sputtering power of the respective TaSi₂ and carbon targets. After analysis by using high resolution transmission electron microscope, the resultant thickness was found to be controlled within ±5% accuracy.

The metallic Cu thin film 110 was also able to be prepared by the methods of CVD, PVD or electro-plating. In the embodiments, the metallic Cu thin film 110 with 100 nm thickness was deposited onto the Ta—Si—C thin film 132 and the metallic Ru thin film 134, such that sandwiched structures of Si/Ta(SiC)/Cu or Si/Ta(SiC)/Ru/Cu were formed, as seen in FIG. 1a and FIG. 1b.

After preparation, the sandwiched structure 100 was rapidly heated from room temperature to a high temperature for a period of time. Subsequently, electrical resistivity of post-annealed sandwiched structure was detected by measuring the sheet resistance at room temperature, using a four-point probe method. When the value of sheet resistance precipitously increases after heating at a certain temperature, it represented that the metallic Cu thin film 110 has diffused to cross the diffusion barrier layer 130 toward the Si material 120 at that heating temperature. This is a result of the formation of copper silicides. It means that diffusion barrier layer has been failed in preventing diffusion of Cu. X-ray diffraction (XRD) was used to identify possible formation of copper silicide and other crystalline phases. The composition of the diffusion barriers layer was analyzed on films purposely deposited to a thickness larger than 1 μm prepared under the same conditions using a field-emission electron probe X-ray microanalyzer (FE-EPMA). Table II shows the atomic composition of Ta—Si—C thin films 132.

TABLE II
The atomic composition of Ta—Si—C thin films at different sputtering
powers of carbon target, measured by FE-EPMA.

| Power of C target | | | | |
|---|---|---|---|---|
| (Watt) | Si (at. %) | Ta (at. %) | C (at. %) | Chemical formula |
| 0 | 63 | 34 | 2.1 | Ta(Si_{0.97}C_{0.03})_{1.9} |
| 100 | 37 | 39 | 24 | Ta(Si_{0.6}C_{0.4})_{1.5} |
| 200 | 33 | 33 | 34 | Ta(Si_{0.5}C_{0.5})₂ |

The embodiments and characteristics of diffusion barrier layer are showing in the following examples:

### EXAMPLE 1

### Properties of TaSi₂ Thin Film With or Without Carbon Addition

As shown in Table II, analyzed composition of as-deposited thin film using single target TaSi₂ (without carbon addition) shows that a ratio of Si to Ta is 1.9, slightly deviated from that of target (which has a Si/Ta ratio 2). It contains a subtle amount of carbon, 2.1 at. % by analysis. The resultant atomic ratio between Ta, Si, and C is Ta(Si_{0.97}C_{0.03})_{1.9}. The existence of carbon in the as-deposited Ta-Si film comes from the carbon-containing sputtering system. By tuning the power of carbon target, Ta—Si—C films with different carbon contents could be attained, as depicted in Table II.

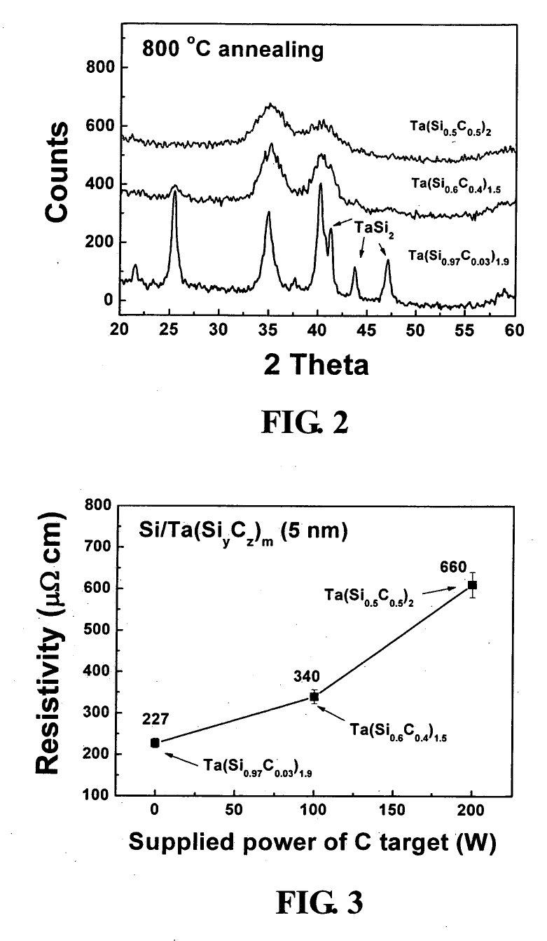

FIG. 2 shows X-ray diffraction patterns for the Ta(Si_{0.97}C_{0.03})_{1.}, Ta(Si_{0.6}C_{0.4})_{1.5} and Ta(Si_{0.5}C_{0.5})₂ films after annealing at 800° C. for 30 minutes. There appear diffraction peaks identifiable as TaSi₂ phase in annealed Ta(Si_{0.97}C_{0.03})_{1.9} film wherein carbon was not purposely added. This depicts that thermal stability of Ta(Si_{0.97}C_{0.03})_{1.9} film is lower than 800° C., so that crystallization occurs. However, thermal stability of Ta(Si_{0.6}C_{0.4})_{1.5} film (with carbon content 24 at. %, Table II) and Ta(Si_{0.5}C_{0.5})₂ film (with carbon content 34 at. %) are much improved since the structure remains mainly amorphous similar to that of as-deposited one.

In FIG. 3, electric resistivity of Ta—Si—C thin films increased with increasing carbon content. The measured electrical resistivity is smaller than 700 μΩ-cm when carbon content is less than 30 at. %; and it is less than 1000 μΩ-cm in the whole composition range of our other studies.

### EXAMPLE 2

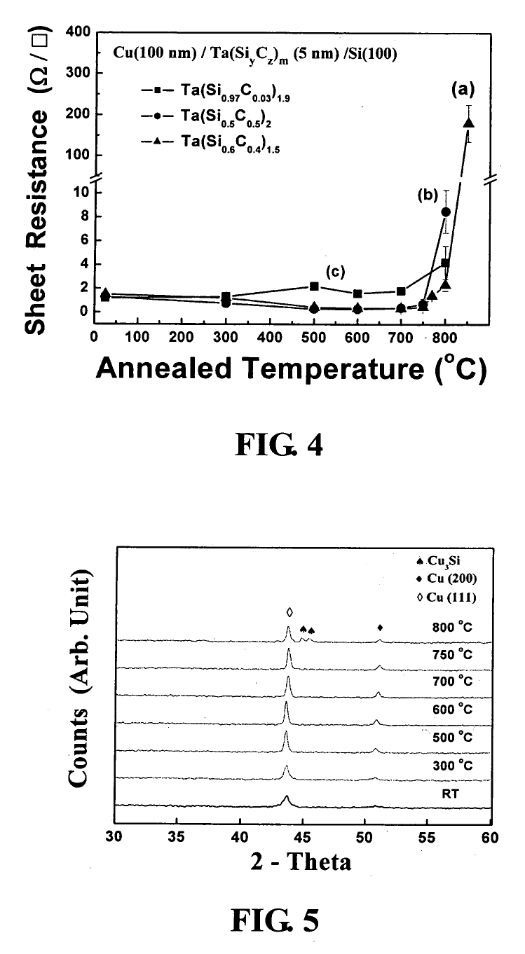

The performance of 5-nm-thick single-layer Ta—Si—C diffusion barrier layers In this example, Ta—Si—C thin films at a well-controlled thickness of 5 nm with different compositions were sandwiched between the metallic Cu thin film and the silicon material and annealed at high temperatures. FIG. 4 shows the change in sheet resistance of Si/Ta—Si—C/Cu sandwich structure after annealing for 1 minute at different temperatures. Curve (a) from Si/Ta(Si_{0.6}C_{0.4})_{1.5}/Cu exhibits a stable and smooth curve after annealing at 700° C. and below. However, the sheet resistance gradually increases starting at 750° C. This reveals that Si/Ta(Si_{0.6}C_{0.4})_{1.5}/Cu is able to retard Cu diffusion up to 700° C. For curve (b), Si/Ta(Si_{0.5}C_{0.5})₂/Cu thin film is stable after annealing at 750° C. and below. The sheet resistance abruptly increases at 750° C. It was analyzed and proved that a portion of Cu atom has diffused through the diffusion barriers Si/Ta(Si_{0.6}C₀₄)_{1.5}/Cu and Si/Ta(Si_{0.5}C_{0.5})₂/Cu at 700 and 750° C., respectively. The diffused Cu reacts with Si material to form crystalline copper silicide and causes the rise in sheet resistance. The more the silicide forms the higher is the resistance rise. Curve (c) from that of Si/Ta(Si_{0.97}C_{0.03})_{1.9}/Cu, which is in fact without carbon addition, the sheet resistance is raised after annealing at a relatively low temperature (400° C.). FIG. 5 shows XRD patterns of Si/Ta(Si_{0.6}C_{0.4})_{1.5}/Cu sandwich structure annealed at different temperatures for 1 minute. We can observe there are two obvious tendencies in peak evolution of Cu (111) and (200) below or beyond 700° C. For the diffractions Cu (111) and (200), the intensity increases with increasing annealing temperature, when annealing temperature is below 700° C. This is due to the grain growth of Cu. However, they start to decrease at 750° C. It means that Cu has begun to diffuse into and crossed diffusion barrier layer toward the Si material and reacted therewith. The results are much conformable to the results in FIG. 4.

### EXAMPLE 3

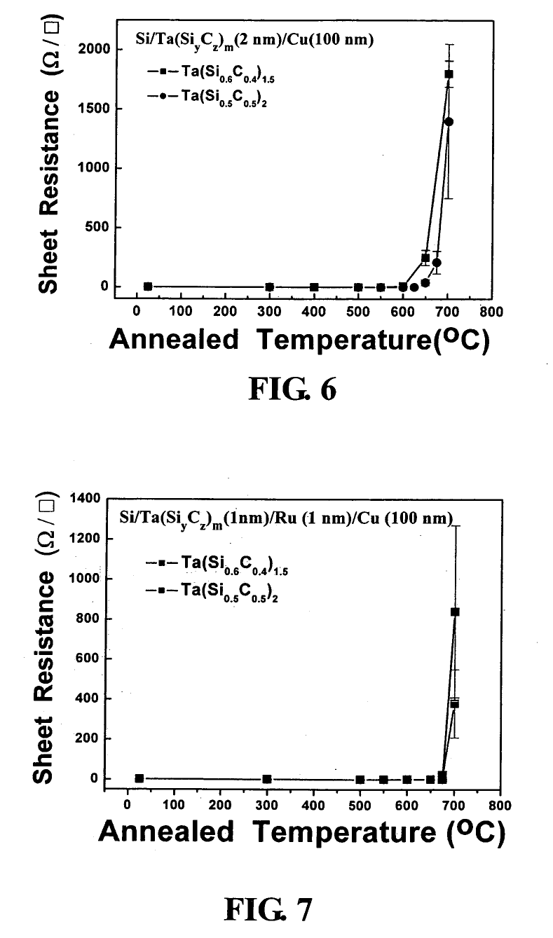

The performance of 1.6 to 2 nm Ta—Si—C single layer diffusion barrier layers In this example, Ta—Si—C thin films at a well-controlled thickness of 1.6 nm or 2 nm with different compositions were sandwiched between the metallic Cu thin film and the silicon material and annealed at high temperatures. The failure temperature, which is inspected by the temperature when a sudden rise of sheet resistance is observed, of the sandwich structures Si/Ta(Si_{0.6}C_{0.4})_{1.5} (2 nm)/Cu and Si/Ta(Si_{0.5}C_{0.5})₂ (2 nm)/Cu was identified to be 600 and 650° C., respectively, as shown in FIG. 6. These temperatures (6.00 and 650° C.) are higher than the processing temperature of back-end of line (BEOL) processes in IC industry, 450° C. Therefore, the single layer Ta(Si_{0.6}C_{0.4})_{1.5} and Ta(Si_{0.5}C_{0.5})₂ at the thickness 2 nm will be qualified to meet the requirement of 27 nm technology node in 2016.

From our studies on the Ta—Si—C layer 1.6 nm thickness, we found that the sandwich structure layered Si/Ta(Si_{0.5}C_{0.5})₂ (1.6 nm)/Cu is able to inhibit Cu diffusion at 600° C. for 1 minute.

### EXAMPLE 4

The performance of composite diffusion barrier layer with the metallic Ru thin film and the Ta—Si—C thin film having a thickness of 1 nm, respectively:

In this example, a composite diffusion barrier layer consisting of the metallic Ru thin film (either polycrystalline or amorphous structure) and the Ta—Si—C thin film, wherein the composite diffusion barrier layer is sandwiched between the metallic Cu thin film and the silicon material and annealed at high temperatures. FIG. 7 shows the change in sheet resistance after annealing for the sandwich structure Si/TaSi-C (a thickness of 1 nm)/Ru (a thickness of 1 nm)/Cu, wherein the Ta—Si—C thin film has different compositions. It is manifest that both sandwich structures withstand a failure temperature 675° C., irrespective of the two Ta—Si—C compositions This is remarkable. Since metallic Ru is immiscible to Cu, its use as diffusion barrier layer benefits in preventing Cu diffusion at high temperatures. Besides, metallic Ru also brings the advantages of (1) low electrical resistivity (17 μΩ-cm for bulk Ru) and (2) excellent adhesion as a buffer layer between Cu and diffusion barrier layer. Accordingly, the insertion of an additional Ru film, even at a thickness 1 nm, is able to not only improve electrical property of Ta—Si—C film but also enhance the adhesion between Cu and Ta—Si—C thin film.

From our other studies on the performance of composite diffusion barrier layer with different thickness, as the thickness of composite Ta—Si—C/Ru thin film is reduced to 1.6 nm, it is still able to prevent Cu diffusion at 650° C. for 1 minute. This is true for the thickness of either Ta—Si—C or Ru to be within the range 0.6 to 1.0 nm, and for the studied compositions of Ta(Si_{0.6}C_{0.4})_{1.5} and Ta(Si_{0.5}C_{0.5})₂.

### EXAMPLE 5

In this example, performances of the diffusion barrier layer, Ta(Si_{y}C_{z})ₘ films, with various compositions by tuning values of y, z, m were explored. We found that at values of lower m (that is 0.7<m<1.4) and higher y/z (that is 3≦y/z<9), the thin films shows greatly reduced electrical resistivity. This is due to the increase of Ta content and decreased carbon content. For example, as the value of m is reduced from 2 to 0.9, electrical resistivity of Ta—Si—C thin film is reduced from 660 to 200 μΩ-cm, depending on the value of y/z. On the contrary, increasing the value of m (that is 1.4≦m<2.1) and decreasing y/z (that is 0.9<y/z<3), the failure temperature can be increased due to decreased Ta content and increased carbon content. For example, as the value of m is increased from 1.5 to 2 and y/z is reduced from 1.5 to 1.0 (reference to example 3), the failure temperature of 2 nm single Ta—Si—C diffusion barrier layer is enhanced from 600 ° C. to 650 ° C. Therefore, the composition of Ta—Si—C thin film for different purposes can be well optimized according to the requirements of device characteristics in real case. Accordingly, those who fully understand the previously stated techniques can easily obtain high adhesion and high failure temperature diffusion barrier layers (0.6˜1 nm Ru/0.6 nm˜1 nm Ta—Si—C) with various compositions of Ta—Si—C, by referring to previously stated examples and descriptions of embodiments.

In our invention, the ultra-thin diffusion barrier materials were disclosed of single-layer ternary Ta—Si—C and by composite layers of Ru/Ta—Si—C, respectively, both of which can sustain high annealing treatment at around 600˜850° C. with highly thermal stability, depending on the thickness, composition, and structure of diffusion barrier layer. These proposed material systems disclosed herewith have benefits being highly compatible with current semiconductor processing, and they are simple to prepare. Besides, Ta—Si—C and Ru/Ta—Si—C diffusion barrier layers, with the total thickness over 1.6 nm, can sustain the high processing temperature with good blocking ability in preventing Cu from diffusion through at higher temperatures and inhibit the formation of copper silicides.

Besides, our invention is an innovation using solid C to replace state-of-the-art gaseous in forming amorphous Ta or Ta-Si compounds. The replacement by solid C is able to reduce the complexity of formation processes and easy tuning in composition to tradeoff performance of the diffusion barrier layer. According to the invented composition range in these new materials, a series of systematical studies have performed to demonstrate their ability, at an extremely thin thickness, to sustain stability of amorphous phase at high temperatures (higher than 600° C.) whereas to retard copper atom from diffusion through. Such diffusion barrier layers meet the requirements of Cu metallization for a trench width of 27 nm and smaller of technology node.

The composition, structure and technologies disclosed in the embodiment(s) of this invention are to exemplify performances of Ta—Si—C and Ru inserted Ta—Si—C diffusion barrier layers, at an extreme thickness of 1.6 nm to 5 nm. It will be appreciated by those skilled in the art that changes could be made to the embodiment(s) described above without departing from the broad inventive concept thereof. It is understood, therefore, that this invention is not limited to the particular embodiment(s) disclosed, but it is intended to cover modifications within the spirit and scope of present inventions as defined by the appended claims. Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A diffusion barrier layer applied in copper metallization of semiconductor device processing technology, the diffusion barrier layer comprising a Ta—Si—C thin film comprising three elements of tantalum (Ta), silicon (Si), and carbon (C) and expressed as Ta(Si_{y}C_{z})ₘ, wherein y, z, and m represent the atomic ratio for each element and obey the following limitations:
0.7<m<2.5,
0.9<y/z<9, and y+z=1.

2. The diffusion barrier layer as claimed in claim 1, wherein the Ta—Si—C thin film is amorphous in structure.

3. The diffusion barrier layer as claimed in claim 1, wherein the diffusion barrier layer is able to retard copper atom from diffusion at a temperature at least 600° C. for 1 minute without any failure.

4. The diffusion barrier layer as claimed in claim 1, wherein the electrical resistivity is not more than 1000 μΩ-cm.

5. The diffusion barrier layer as claimed in claim 1, wherein 1.4≦m<2.1, 0.9<y/z<3.

6. The diffusion barrier layer as claimed in claim 1, wherein 0.7<m<1.4, 3≦y/z<9.

7. The diffusion barrier layer as claimed in claim 1, wherein the Ta—Si—C thin film further comprise a fourth element: oxygen.

8. The diffusion barrier layer as claimed in claim 1, wherein the Ta—Si—C films are prepared by one method chosen from one of chemical vapor deposition and physical vapor deposition.

9. The diffusion barrier layer as claimed in claim 1, wherein the thickness of the Ta—Si—C thin film is not less than 1.6 nm.

10. A composite diffusion barrier layer applied in copper metallization of semiconductor device processing technology, the composite diffusion barrier layer comprising a Ta—Si—C thin film and a metallic ruthenium (Ru) thin film deposited on the Ta—Si—C film, the Ta—Si—C thin film comprising three elements of tantalum (Ta), silicon (Si), and carbon (C) and expressed as Ta(Si_{y}C_{z})ₘ, wherein y, z, and m represent the atomic ratio for each element and obey the following limitations:
0.7<m<2.5,
0.9<y/z<9, and y+z=1.

11. The composite diffusion barrier layer as claimed in claim 10, wherein the metallic Ru thin film is in either polycrystalline or amorphous structure.

12. The composite diffusion barrier layer as claimed in claim 10, wherein the diffusion barrier layer is able to retard copper from diffusion through at a temperature at least 650° C. for 1 minute without any failure.

13. The composite diffusion barrier layer as claimed in claim 10, wherein the diffusion barrier layer comprising metallic Ru thin film and the Ta—Si—C thin film having an electrical resistivity smaller than that of the diffusion barrier layer comprising the single Ta—Si—C thin film.

14. The composite diffusion barrier layer as claimed in claim 10, wherein metallic Ru thin film is prepared by one method chosen from one of chemical vapor deposition and physical vapor deposition.

15. The composite diffusion barrier layer as claimed in claim 10, wherein the thickness of the Ta—Si—C thin film is not less than 1.6 nm.

16. A sandwiched structure applied in Cu metallization of semiconductor device processing technology, the sandwiched structure comprising:
a metallic Cu thin film and a Si material; and
a diffusion barrier layer disposed between the metallic Cu thin film and the Si material, and comprising a Ta—Si—C thin film comprising three elements of tantalum (Ta), silicon (Si), and carbon (C) and expressed as Ta(Si_{y}C_{z})ₘ, wherein y, z, and m represent the atomic ratio for each element and obey the following limitations:
0.7<m<2.5,
0.9<y/z<9, and y+z=1.

17. The sandwiched structure as claimed in claim 16, wherein diffusion barrier layer is able to retard copper atom from diffusion toward the Si material.

18. The sandwiched structure as claimed in claim 16, wherein the Si material is one of Si wafer and Si-based films in IC devices.

19. A sandwiched structure applied in Cu metallization of semiconductor device processing technology, the sandwiched structure comprising:
a metallic Cu thin film and a Si material; and
a diffusion barrier layer disposed between the metallic Cu thin film and the Si material, and comprising a Ta—Si—C thin film and a metallic ruthenium (Ru) thin film deposited on the said Ta—Si—C film, the Ta—Si—C thin film comprising three elements of tantalum (Ta), silicon (Si), and carbon (C) and expressed as Ta(Si_{y}C_{z})ₘ, wherein y, z, and m represent the atomic ratio for each element and obey the following limitations:
0.7<m<2.5,
0.9<y/z<9, and y+z=1.

20. The sandwiched structure as claimed in claim 19, wherein diffusion barrier layer is able to retard Cu atoms from diffusion toward the Si material.

21. The sandwiched structure as stated in claim 19, wherein the Si material is one of Si wafer and Si-based films in IC devices.
